(19) United States
(12) Patent Application Publication
(10) Pub. No.: US 2004/0137376 A1
(43) Pub. Date: Jul. 15, 2004

(54) Method and system for replicating film data to a metal substrate and article of manufacture

(76) Inventors: John L. Bishop, Santa Fe, NM (US); Michael A. Wheeler, Portland, OR (US); Kenneth M. Harrington JR., Portland, OR (US)

Correspondence Address: Gary D. Lueck, Bingham McCutchen, LLP, Suite 1800, Three Embarcadero Center, San Francisco, CA, 94111-4067, US

(21) Appl. No.: 10/346,047

(22) Filed: Jan. 15, 2003

(51) Int. Cl. G03F 7/20

(52) U.S. Cl. 430/324; 430/5; 430/16; 430/322

(57) ABSTRACT

A method and system for recording or replicating data in a film media to a metal substrate, such as a nickel substrate. An ultraviolet light source is directed to a sheet of microfiche. The resulting microfiche image is collimated and reduced with an optics system. The reduced image is directed to a wafer of silicon. The silicon wafer is developed, resulting in a mask representative of the documents or data in the film media. A metal seed or base layer is developed on the mask. One or more metal layers are deposited onto the seed layer to form a metal substrate having the film media data or documents formed therein.

### FIELD OF THE INVENTION

The present invention relates to storing data to a metal material or substrate, and more particularly, to a method and system for replicating data or images in a film or film media to a metal material, substrate, plate or wafer or other metal or metallic product and an article of manufacture of a metal substrate having film media data formed therein.

### DESCRIPTION OF RELATED ART

There are many known techniques, devices and materials for storing data. Common storage materials or media include magnetic storage devices such as floppy and hard disks, optical media such as a Compact Disc Read Only Memory (CD-ROM), Compact Disc Read-Write (CD-RW), and film media such as microfilm or microfiche. Different storage materials have different storage capabilities and lifetimes. For example, some magnetic and optical disks have lifetimes of about 10 years. Some film materials, such as microfiche, have lifetimes of about, for example, 50 years. Other optical archive systems that use more durable film materials can store data for up to about 100 years.

Data stored in magnetic or optical media can be lost if the storage medium can not store data for the required length of time. Further, data formats can change over time. More specifically, with different and new electronic, magnetic and optical technologies, data formats and corresponding storage media and devices can evolve, change or be replaced. Thus, data that is stored in one format or configured for one device may not be compatible with a new data format or new device. These types of technology improvements or replacements are particularly problematic with magnetic and optical data formats. Consequently, storing, retrieving and processing data in old or incompatible data formats can be inconvenient and costly. Thus, microfilm and microfiche are commonly used for archive purposes since data stored in a film can be retrieved using standard optical or microscope systems.

Film data can also be adapted to or configured for different storage devices or formats. Since film data is generally less complicated than other analog and digital media and formats, it can be used in connection with many different formats and converted, as necessary, for storage in different types of media and devices. Moreover, film typically has a longer lifetime compared to magnetic or optical media and is, therefore, generally preferred for data archives or extended storage applications.

Known film-based storage media, however, also have a number of shortcomings. Film materials, like magnetic and optical materials, are also degradable and have limited lifetimes. Thus, while film typically has a longer lifetime than magnetic and optical media, its lifetime is still limited, e.g., 50-100 years. In addition to inherent degradation, film is also susceptible to damage from various environmental factors. For example, film can be damaged or destroyed when exposed to fire, water, oxidation or humidity. These environmental factors can cause significant data loss which, in turn, can lead to substantial monetary losses. Additionally, film is typically stored in sheets or rolls. Sections of film sheets or rolls can stick together due to humidity or moisture. When film sheets or rolls that are stuck together are later separated, they can be damaged, thereby resulting in lost data. A further exemplary shortcoming is that film-based media can require significant space as a result of being stored on reels. Another shortcoming is that viewing data stored in a roll or sheet of film requires manipulation and positioning of the roller sheet such that the desired image appears in focus. The searching and alignment processes can be tedious depending on the quantity of film, desired zoom and arrangement of images.

A need, therefore, exists for a method and system that can accurately replicate and record data, documents and images stored in a film to a more durable media, store the data for extended periods of time, provide data integrity and durability, be immune or resistant to environmental factors, store data in a condensed form, and enable stored data to be retrieved and used with different applications and data formats- in an efficient manner. A need also exists for an article of manufacture that serves as a durable and stable metal substrate or other metal or metallic product for storing images, data or documents stored in a film.

### SUMMARY OF THE INVENTION

According to one aspect of the present invention, film and a base wafer with photoresist are placed in an exposure system. The film can be microfilm or microfiche. A light source is activated, and the photoresist is exposed to a pattern derived from the film images, data or documents. The light source can be an ultraviolet (UV) light configured to emit radiation at a wavelength of about 280 nm to about 400 nm, or any other wavelength that does not burn or brown the film. As a result, a mask of the film image or pattern is formed on the base wafer when the photoresist is developed.

The base wafer with photoresist can be exposed by placing the film directly onto the photoresist or by projecting one or more patterns derived from the film onto the photoresist. The pattern can represent or correspond to an image, a photograph, text, or other types of data stored in the film, such as images of a barcode or matrix stored in the film. A metal substrate is formed having the film patterns formed therein. The metal substrate can be, for example, nickel, gold or platinum. The metal substrate can be formed using a metal seed or base layer and then depositing one or more additional layers over the seed layer. The metal substrate can also be formed using an etching process.

In the direct exposure system, the light source is activated to expose the photoresist to the pattern derived from the film. The photoresist is then developed to produce the mask of the film pattern. The mask is used to replicate the pattern originally stored in the film to a metal substrate, such as a nickel substrate.

In the projection exposure system, the photoresist is exposed to patterns derived from the film through one or more optical components, such as one or more lenses. An initial image of the film pattern is projected through the optical components to form a second image. The second image is projected onto the photoresist to expose the photoresist to pattern derived from the film. Lenses can reduce the size of the initial image such that the photoresist is exposed with smaller film patterns. As a result, smaller images can be formed in the metal substrate, thereby providing expanded and more durable data storage capabilities.

Developing a metal substrate from a metal seed or base wafer involves one or more metal layers being deposited over the seed layer to form the metal substrate. The seed or base layer can be formed or deposited onto the mask using a sputter mechanism. One or more additional layers are then deposited onto the seed layer using, for example, an electroplating system, to form the metal substrate. The base wafer and the metal substrate with film data formed therein are then separated.

An additional aspect of the present invention is related to photoresist being applied to a nickel base substrate. Photoresist is exposed with the images of the film, and a mask is formed on the nickel substrate when the photoresist is developed. The nickel substrate with the mask is then placed in an etch solution. As a result, nickel sections are removed or etched away from the nickel substrate where the photoresist was exposed to the film images (depending on whether positive or negative photoresist is utilized). After removing the photoresist, the resulting nickel substrate has the pattern corresponding to or representative of the film data or images etched or formed therein. Nickel sections of the nickel base substrate can also be removed using reverse electroplating.

A further aspect of the present invention is directed to replicating data stored in a metal substrate in a plastic or other pliable sheet or material. The plastic sheet is placed against a metal substrate having the film pattern or image formed therein and subjected to heat and pressure. As a result, the plastic sheet forms within or around impressions or ridges in the metal substrate corresponding to the film pattern. As a result, a plastic sheet is formed with the pattern of film images or data. Thus, the metal substrate and the plastic sheet are negatives of each other, but both have the film images or data formed therein.

### BRIEF DESCRIPTION OF THE DRAWINGS

Referring now to the drawings in which like reference numbers represent corresponding parts throughout:

FIG. 1 is a general block flow diagram of steps performed to expose a base wafer coated with photoresist to a pattern derived from an image or pattern of a mask representing the pattern and to replicate the film pattern to a metal substrate with the mask;

FIG. 2 is a system flow diagram of components used to inspect a microfiche sheet and a base wafer with photoresist;

FIG. 3 is a system diagram of steps for directly exposing photoresist of a base wafer and a mask produced when the photoresist is developed;

FIG. 4 is a system diagram of the exposure of photoresist on a base wafer with film images or patterns derived from the film through an optical projection system;

FIG. 5 is a system flow diagram of the formation of a metal base or seed layer over the mask representing the film patterns or images;

FIG. 6 is a side view of layers deposited onto the base wafer after the seed layer is formed;

FIG. 7 is a system flow diagram showing one or more additional metal layers being deposited onto the base or seed metal layer;

FIG. 8 is a flow diagram of the formation of a metal substrate using an etching process;

FIG. 9 illustrates formation of a nickel substrate with film patterns formed therein using reverse electroplating;

FIG. 10 illustrates separation of a base wafer and a metal substrate and impressions representing film patterns, images or data formed in an underside of the metal substrate;

FIG. 11 is a system flow diagram of the final inspection and processing of a finished metal substrate after separation of the metal substrate from a base wafer; and

FIG. 12 is a system flow diagram showing replication of a pattern in a film formed in a nickel substrate to a plastic sheet, and replication of the film pattern formed in a plastic sheet to a nickel substrate.

### DETAILED DESCRIPTION OF THE PREFERRED EMBODIMENT

In the following description, reference is made to the accompanying drawings which form a part hereof, and which show by way of illustration specific embodiments by which the invention may be practiced. It is to be understood that other embodiments may be utilized, as structural changes may be made without departing from the scope of the present invention.

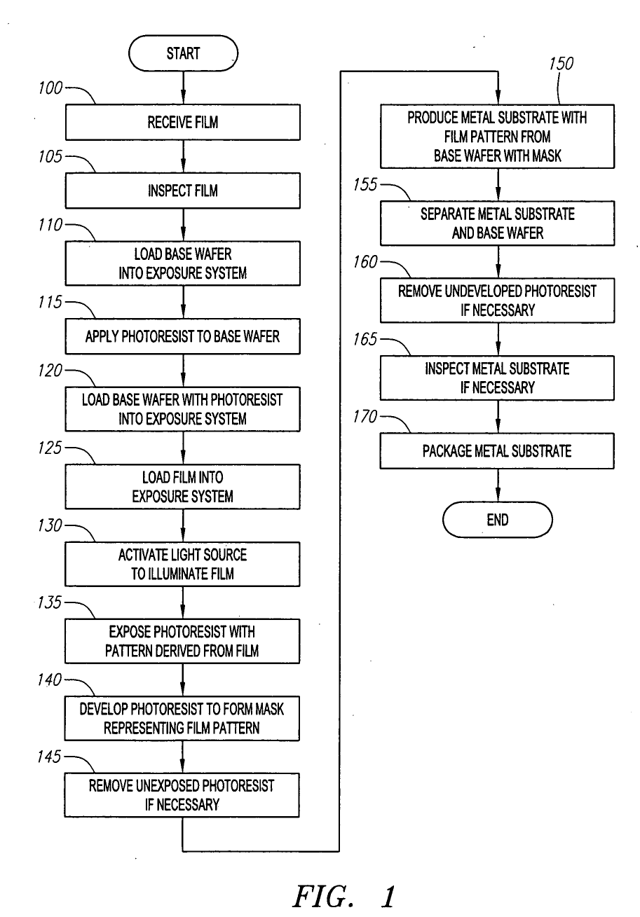

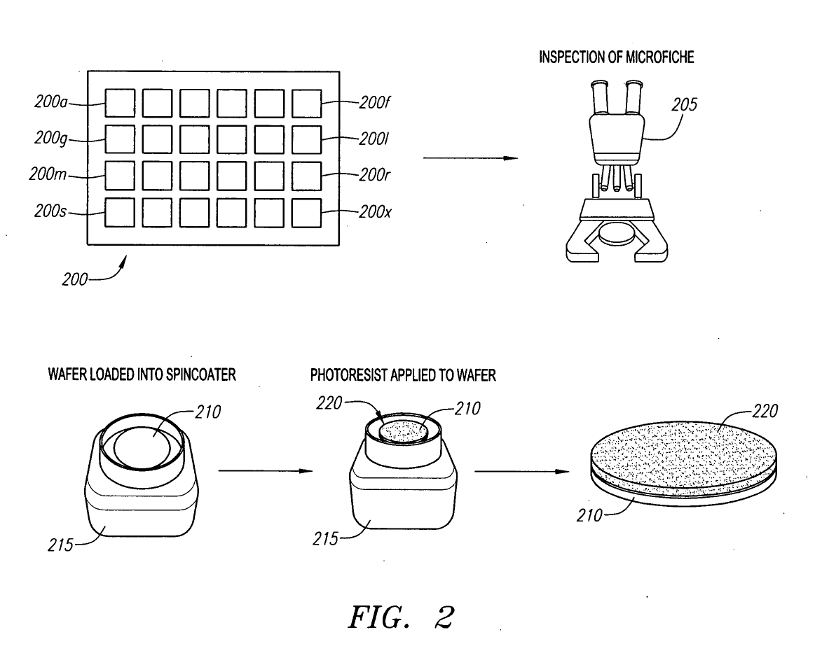

The present invention is generally directed to recording, storing or replicating data or images in a film media or other film material (hereafter generally referred to as “film”) to a metal or metallic substrate (hereafter generally referred to as “metal substrate”). Persons of ordinary skill in the art will recognize that a “metal substrate” can be various types and forms of metal materials or products, including, but not limited to, a metal or metallic wafer, plate, substance, base, material or other metal piece. However, for purposes of explanation, this specification refers to a “metal substrate” as a metal material with film images formed therein. The method of replicating patterns derived from film, such as images, data, documents or other information, to a metal substrate is generally illustrated and described in FIG. 1. Then, further details relating to different methods and components for film image replication are described in FIGS. 2-12.

Referring to FIG. 1, in step 100, film is received for processing. Many different types of film or film media can be processed by the present invention including, but not limited to, microfiche, microfilm, projector film, camera film negative, and other types of film that are not opaque to light (generally referred to as “film”). For purposes of illustration and explanation, this specification refers to microfilm and microfiche, and preferably, microfiche. Microfilm is typically configured as a roll of film with individual documents or images. Microfiche is typically configured as individual film sheets with images of individual documents.

For example, referring to FIG. 2, a microfiche sheet 200 can include different numbers of images of different types of information. One exemplary microfiche sheet 200 includes 24 images (200a-x) arranged in a 4×6 configuration. Persons of ordinary skill in the art will recognize that various other films with different numbers and types of images and data can also be utilized, and that microfiche is utilized as an example.

Film can store images representing various types of analog and digital data and information. For example, film can store black and white, grayscale, or color images or photographs, images, documents, text (alpha, numeric, or alpha-numeric), records, or digital data or digital representations of data such as a bar-code, matrix, or other data formats or symbols. However, for purposes of illustration and explanation, this specification generally refers to “images” or “patterns” stored in a film or microfiche sheet, however, such images or patterns can be many different types of data.

Additionally, persons of ordinary skill in the art will recognize that the present invention can be used in connection with various customers and applications. For example, libraries, businesses, universities and government agencies all use various types of film to store different types of images with various data and information. The present invention can be used to replicate film images to a metal substrate in connection with many applications including, but not limited to, data archives, personal record archiving, library collections, newspapers, magazines and other periodicals and publications, and government, business and financial records.

Continuing with FIG. 1, step 105, the microfiche sheet can be inspected for damage or other irregularities. A visual inspection of the microfiche sheet can indicate that two or more sheets are stuck together due to, for example, humidity or heat. In this case, the sheets are separated while attempting to minimize any damage.

Then, the base wafer with photoresist is prepared. This specification refers to a “base wafer” as the wafer that receives photoresist. Thus, the “base wafer” includes a mask of the film images from the photoresist. Specifically, in step 110, a base wafer is loaded into a spin coating mechanism or other coating device. In step 115, a layer of photoresist is applied to a top surface of the base wafer using the spin coating mechanism. An exemplary base wafer that can be used with the present invention is a silicon base wafer. However, persons of ordinary skill in the art will recognize that other base wafers, such as glass and metal base wafers, can also be utilized.

Photoresist is a film or layer that holds or stores a pattern of images to which it is exposed. A positive photoresist holds or stores patterns of the microfiche sheet images when it is exposed to the light source. When the positive photoresist is developed, a mask of the microfiche data is formed on a top surface of the base wafer. Exposed photoresist is removed, leaving a mask representing film images on the silicon base wafer. A negative photoresist, in contrast, holds or stores a pattern corresponding to or representing the microfiche sheet images when it is exposed to a light source. When the negative photoresist is developed, the resulting mask is the negative of the pattern of image data, i.e., unexposed sections are removed and the exposed sections remain on top of the base layer to form a mask or outline representing the film images. Both types of photoresist can be utilized with the present invention, but this specification refers to positive photoresist for purposes of explanation.

Further, various spin coating mechanisms, photoresists, photoresist application techniques, and photoresist development agents can be used depending on the selected materials and operating parameters. Such components and processing techniques are known to persons of ordinary skill in the art and are, therefore, not discussed in further detail.

Referring again to FIG. 2, is a system flow diagram that generally illustrates components are utilized in the previously described steps, the exemplary microfiche sheet 200 includes images or documents 200a-x. The images 200a-x can be inspected with a microscope 205 or other optical or inspection device. Before, coincident with, or after the initial microfiche processing, a silicon base wafer 210 is prepared with photoresist. The base wafer 210 is placed into a spincoater 215 or other wafer processing device, and photoresist 220 is deposited onto the top surface of the base wafer 210. The base wafer 210 with photoresist 220 is then prepared to be exposed with a pattern derived from the film using a light source.

Referring back to FIG. 1, the base wafer with photoresist is loaded and positioned in an exposure system in step 120. In step 125, the microfiche sheet is also placed into the exposure system. Persons of ordinary skill in the art will recognize that it is not necessary to perform steps 100-125 in the exact recited order and different sequences can be performed. Moreover, depending on the condition of the microfiche and substrate, one or more of steps 100-125 may not be necessary.

Continuing with step 130, a light source is activated to illuminate the microfiche sheet. As a result, in step 135, the photoresist on the base wafer 210 is exposed with a pattern derived from the film, e.g., patterns of images stored in the microfiche sheet. In other words, the photoresist holds or stores patterns of the microfiche sheet images. The photoresist can be exposed using various techniques including, but not limited to, utilizing a stepper/scanner system. One exemplary stepper/scanner that can be utilized is the PAS 5500 step and scan system, available from ASML Tempe, 8555 South Riverway Parkway, Tempe, Ariz. Then, in step 140, the photoresist is developed or hardened. As a result, the photoresist representing the microfiche image or pattern hardens into a mask. In step 145, the unexposed photoresist regions are removed from the base wafer 210, leaving a mask representing the microfiche images on a top surface of the base wafer.

In step 150, the base wafer with the photoresist mask is used to produce or generate a metal substrate through the use of, for example, sputtering or electroplating, such that the resulting substrate includes a pattern corresponding to or representing the microfilm images formed therein. As previously discussed, “metal substrate” is used to generally refer to a metal or metallic plate, wafer, or other material that has the film images or data formed therein.

Persons of ordinary skill in the art will recognize that various metal or metallic substrates can be formed with microfiche images. Exemplary metal substrates include nickel, gold and platinum substrates. However, a nickel substrate is discussed further in this specification as a specific exemplary metal substrate since it has a long lifetime, is durable, stable, resistant to environmental factors such as heat and water, and relatively inexpensive.

Continuing with step 155, the nickel substrate having the film images formed therein is separated from the silicon base wafer. Depending on the thickness of the nickel substrate, it can be manually separated from the base wafer by peeling substrate away from the base wafer. Alternatively, the nickel substrate and silicon base wafer can be separated using an appropriate mechanical or chemical system.

Photoresist is then removed from the nickel substrate in step 160, if necessary, thus completing the formation, processing and cleaning of the nickel substrate having “microfiche images” formed therein. In step 165, the nickel substrate is inspected, if necessary, to determine if any processing irregularities occurred and to ensure that the microfiche images were successfully transferred and replicated to the nickel substrate. Then, in step 170, if necessary, the nickel substrate is packaged or configured for further processing or storage.

Having described the general method of replicating images or patterns of images stored in a film to a metal substrate, following are further descriptions and system flow diagrams illustrating various aspects, techniques, and components of the present invention. First, techniques and components for exposing the base wafer with photoresist to a pattern derived from the film (step 135) are described. Then, different techniques and components for generating or producing a metal substrate having film images formed therein based on the mask of the base wafer (step 150) are described. Finally, additional replication applications of the film images or patterns formed in a metal substrate are described.

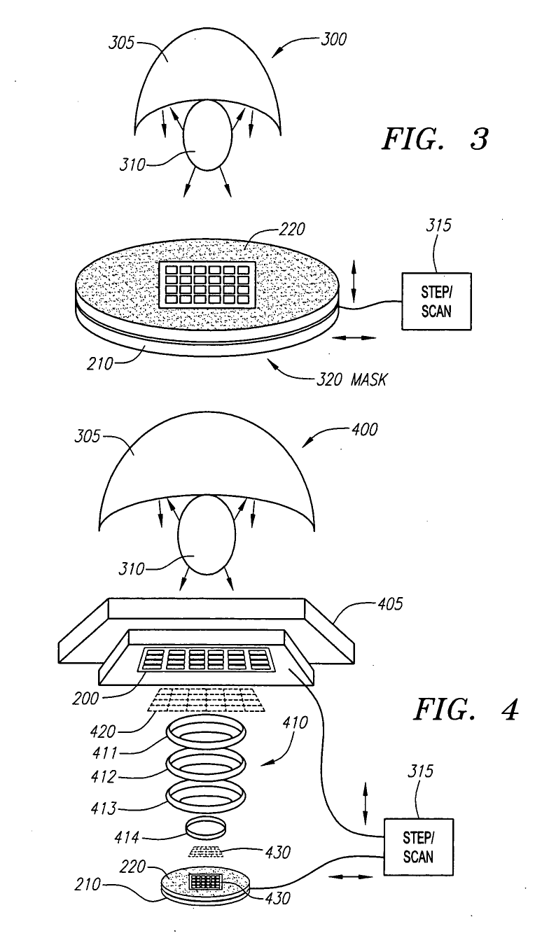

Referring to FIG. 3, an exemplary direct exposure system 300 includes a reflector 305, a light source 310 that emits radiation that is reflected down to the film with the reflector 305, and a step and scan system 315.

The light source 310 and reflector 305 can be configured such that only a portion of the microfiche is exposed by the light source at a time, e.g., by exposing individual images 200, or, alternatively, by exposing groups of images, sections of the microfiche sheet, or the entire film sheet. The wavelength of the radiation can be, for example, 260 nm to 400 mm. Other wavelengths that do not burn or brown the film can also be used. Radiation exposes the base wafer 210 with photoresist 220 to a pattern 320 of the microfiche sheet 200 images.

As a result, the photoresist 220 holds or stores the pattern of images 320 in the film. In one embodiment, the microfiche sheet 200 is placed directly on top of the photoresist layer 220 of the base wafer 210. The light source 305 is activated to emit radiation and expose the photoresist 220 with the pattern 320 derived from the film or microfiche sheet 200. As a result, microfiche sheet images are directly transferred to and stored in the photoresist 220 as pattern 320. When the photoresist 220 is developed, a mask of the pattern representing the microfiche sheet images is formed on or in the base wafer 210. The mask includes sections corresponding to images 200a-x in the microfiche sheet 200.

An exemplary light source 310 that can be utilized is an ultraviolet (UV) light source, including, for example, a mercury lamp or laser that emits radiation at a wavelength of about 260-400 nanometers (nm). The UV light source 310 can be tuned to emit selected wavelengths or be directed through a filter (not shown) that transmits selected wavelengths. A permissible range of UV wavelengths for exposing the photoresist with the pattern can depend on the type and thickness of the sheet 200. For example, a typical microfiche sheet is made of polyester, cellulose acetate, or cellulose nitrate and has a thickness of about 0.007″. This specific exemplary microfiche sheet can be burned or damaged with UV radiation having a wavelength less than about 350 nm. Thus, a preferred operating range of wavelengths for this type of microfiche sheet is about 350-400 nm. A preferred wavelength of 365 nm has been determined to be satisfactory to avoid browning or burning of this type of microfiche sheet. However, different microfiche sheets have different characteristics and thicknesses, and the radiation wavelength can be adjusted accordingly.

Another factor to consider in selecting a UV light source 310 and radiation wavelength is based on the dimensions of the microfiche sheet images 200a-x. For example, images can include letters, numbers and symbols having a height of about 0.002″ to about 0.5″ and a width of about 0.0005″ to about 0.5″. UV radiation having a wavelength of about 260-400 nm is generally acceptable to discriminate letters, numbers and symbols having these dimensions. If images having smaller characters are to be replicated, then a shorter UV wavelength can be utilized to maintain an acceptable resolution so long as the microfiche sheet is not damaged.

One exemplary technique for exposing the photoresist with a pattern derived from the film is utilizing a stepper/scanner 315. In the direct exposure system shown in FIG. 3, the stepper/scanner 315 is configured to move the silicon base wafer 210 (or a stage holding the silicon base wafer) with the photoresist 220 thereon together with the film on the photoresist. The stepper/scanner 315 can be configured to expose the photoresist 220 to different sizes of the sections or portions of an image or pattern in the microfiche sheet 200. For example, in the exemplary microfiche sheet 200 having 24 images 200a-x, the stepper/scanner 315 can be configured to expose or scan a first photoresist section with a first image 200a, step to a second wafer/photoresist section, scan the second photoresist section with a second image 200b, and so on, until all of the appropriate photoresist sections of the sheet 200 are exposed and a mask 320 is formed. Persons of ordinary skill in the art will recognize that each scan by the stepper 315 can result in the illumination of different numbers of images or patterns or different sizes microfiche sheet sections.

Referring to FIG. 4, in an alternative embodiment, the exposure system 400 includes an indirect exposure system, such as a projection or optical system. The projection system includes a microfiche sheet holder or stage 405, an optical system 410, and a stepper/scanner 315. The optical system 410 can include, for example, one or more lenses 411-414 to collimate and/or reduce the film images. The base wafer 210 with photoresist 220 can be exposed to a pattern 430 derived from the microfiche sheet 200 by projecting an initial film image or pattern 420 through the optical system 410 to form a second or projected film image or pattern 430. The second or projected film pattern 430 is directed onto the photoresist. The photoresist holds or stores the second pattern 430 of the microfiche sheet images. When the photoresist is developed, a mask representing the projected pattern 430 of images is formed.

This exemplary indirect projection exposure system 400 is configured such that the light source 305 emits radiation 310 in the wavelength ranges previously described. The microfiche holder or stage 405 is positioned such that the microfiche sheet 200 secured thereby is illuminated by the light source 305 above. Persons of ordinary skill in the art will recognize that various other optical components besides, or in addition to, lenses 411-414 can also be utilized to project an image of the film. For example, the optical system 410 can include one or more mirrors and/or prisms (not shown) to focus, reduce, or direct the image of the film data as needed. Further, the light source 305, microfiche sheet 200, microfiche holder 405 and collimating and reducing optics 410 are illustrated as arranged in a linear configuration. The exposure system 400, however, is not so limited. A non-linear configuration with, for example, a mirror can also be used. Further, one or more mirrors or other reflective and refractive components can project, collimate and reduce the size of the initial image pattern 420 to a reduced or second image pattern 430.

The optical system lenses 411-414 can collimate the image(s) of the microfiche sheet, as well as reduce the size of the initial pattern 420 to form a smaller, more condensed second or projected image pattern 430 formed in the photoresist. An exemplary reduction ratio of an original or first image pattern 420 to a second or reduced image pattern 430 formed in the photoresist is about 4:1. In other words, the projected image pattern 430 is about ¼ of the size of the initial image pattern 420. Of course, persons of ordinary skill in the art will recognize that other reduction ratios can be utilized. Thus, other lens and optical component configurations and reduction factors can be selected to project different sizes of microfiche images as needed for each application or storage requirement.

In the indirect exposure system 400, the stepper/scanner 315 can be configured such that the microfiche sheet stage 405 and base wafer 210 with photoresist 220 are positioned to expose the photoresist 220 to a pattern derived from the microfiche sheet 200. For example, the stepper/scanner 315 can be positioned in an initial position such that the stage 405 and base wafer 210 with photoresist are arranged to expose a first photoresist section to, e.g., first image or pattern or groups of images or patterns. Then, the stepper/scanner 315 can move or step the stage 405 to a second position such that a second sheet image or section is illuminated by the light source 310, and move the base wafer 210 with photoresist 220 such that the corresponding second photoresist section is exposed, and so on, for each microfiche sheet section. Indeed, persons of ordinary skill in the art will recognize that the stepper/scanner 315 and light source 310 and reflector 305 can be configured such that different sheet sections and section sizes can be illuminated (and the photoresist exposed with those selected sections) during each step of the stepper/scanner 315.

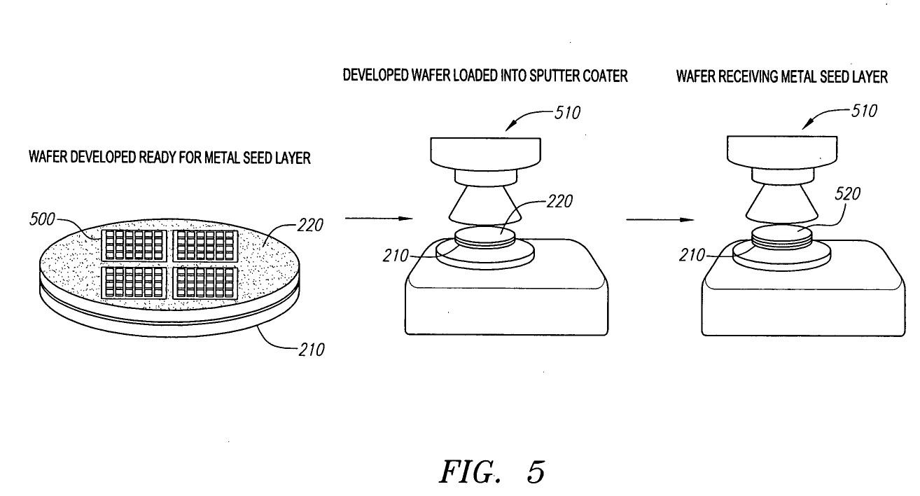

Referring to FIG. 5, developing the photoresist forms a mask 500 representative the pattern of images (320, 430). The mask 500 is used in the development or production of the metal substrate or article of manufacture with patterns of microfiche sheet images 200a-x formed therein. In one embodiment, as shown in FIG. 5, the base wafer 210 with the mask 500 is placed in a sputter coater 510. The sputter coater 510 deposits a seed or base layer 520 over the mask 500 and the base wafer 210. In the exemplary embodiment in which a nickel substrate is produced, the base or seed layer is a Nickel layer 520 with a thickness of a few Angstroms to a few nanometers.

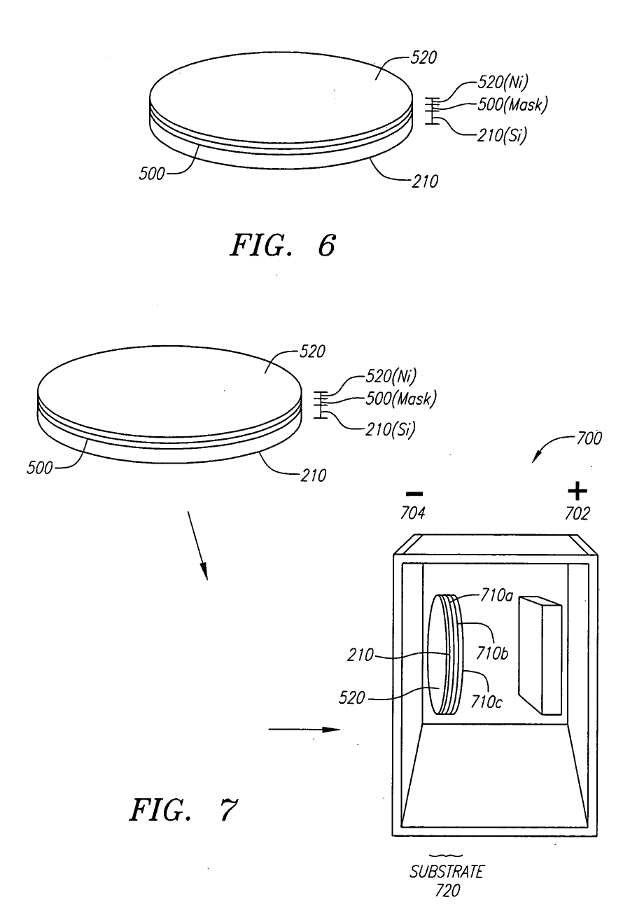

FIG. 6 illustrates a cross-section of the wafer 600 after the base or seed layer 520 has been deposited over the mask 500. Specifically, wafer 600 includes the silicon base wafer 210, the mask 500 formed with the pattern of microfiche sheet images, and the base or seed layer 520 deposited on top of the mask 500 and base wafer 210. As a result, the bottom portion of the seed layer fills in or over the mask 500, to form a pattern representing images 200a-x in the microfiche sheet 200.

Referring to FIG. 7, the silicon base wafer 210 with the metal seed layer 520 deposited thereon is inserted into an electroplating system 700. The silicon base wafer 210 with the seed layer 520 serves as the negative terminal or plate 702. The electroplating system 700 deposits one or more layers 710a-c (generally 710) onto the seed layer 520. The one or more additional layers 710 are deposited from the positive terminal 702 to the negative terminal 704, i.e., to the metal seed layer 520. Specifically, the nickel ions 710a-c are “repelled” by the positive terminal 702 and attracted to the negative terminal 704 and seed layer 520. Thus, a metal substrate 720 is developed or produced as layers 710 are deposited over the seed layer 520. The thickness of the seed layer 520 can be about 10 Angstroms to about 200 nm. The thickness of the one or more additional nickel layers 710 that are deposited onto the seed layer 520 can be about 1.0 mm. Different numbers of layers and thicknesses of layers can also be used. As a result, the bottom surface or underside of the metal substrate 720 has impressions in the shape of the mask (and the images of the microfiche sheet).

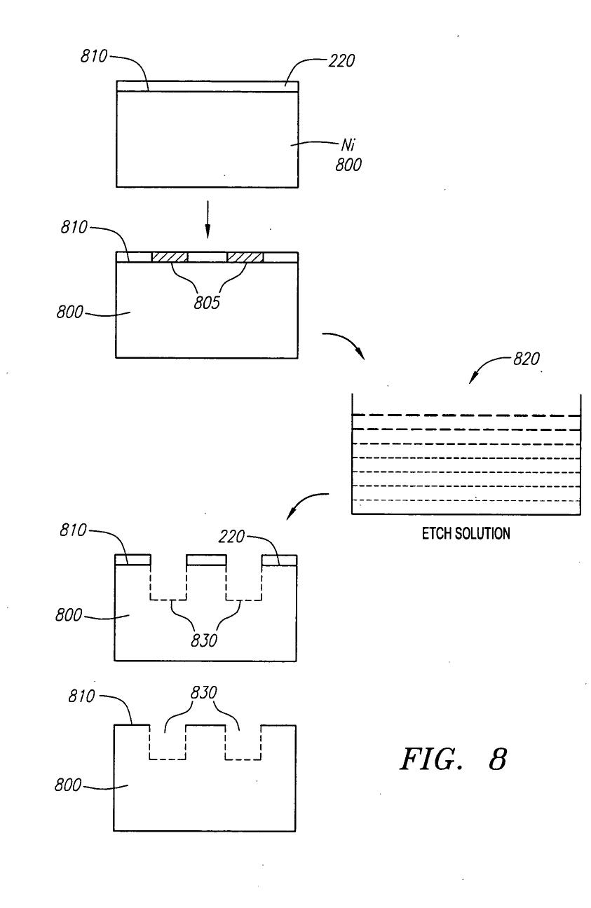

In an alternative embodiment illustrated in FIG. 8, a nickel base wafer 800 (rather than a silicon base wafer as previously described), with photoresist 220 exposed to a pattern derived from the microfiche sheet can be developed or transformed into a metal substrate with the film images formed therein through an etching process. More specifically, if the base wafer is a nickel base wafer 800 then the photoresist 220 acts as a hard mask to an etchant 820. Thus, the pattern of microfiche images 805 in the exposed photoresist 220 is developed down to a top surface 810 of the nickel wafer 800. The nickel wafer 800 is then placed in the etch solution 820. The etch solution 820 removes nickel 830 where the photoresist 220 was developed down to the top surface 810 (removed nickel sections represented as dotted lines). The remaining photoresist 220 is then removed. As a result, a nickel “substrate” with representations of the microfiche sheet images where nickel sections 830 were removed is developed by the etching process being applied to the “nickel base wafer.”

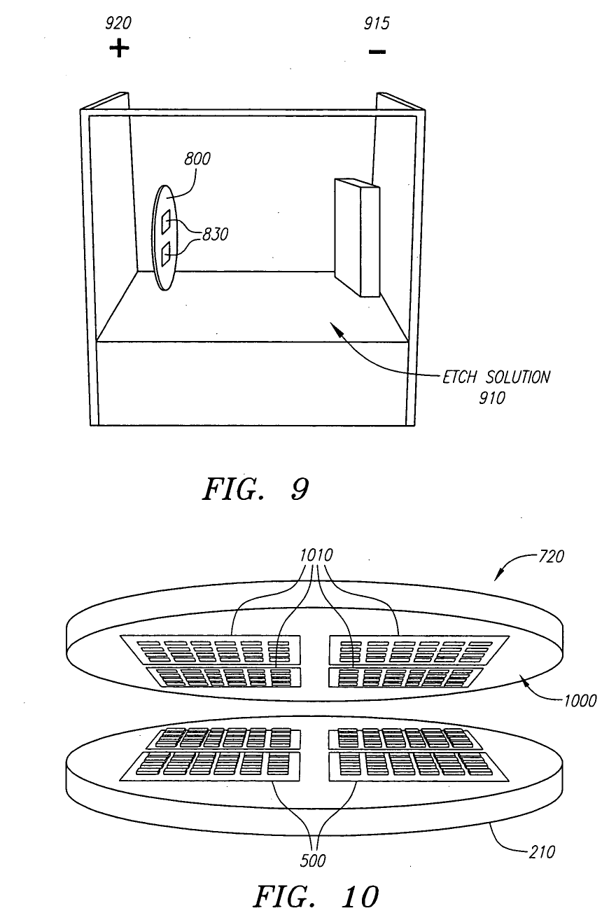

In yet a further alternative embodiment, the transformation can be performed by reverse electroplating. For example, referring to FIG. 9, a nickel wafer or disk is exposed with a mask and developed. The nickel disk is then placed in an solution 910. The nickel disk serves as the anode (+) and the system also includes a cathode (−) 920. Specifically, instead of using an etchant as previously described, nickel sections 830 can be removed from the nickel substrate 800 by reverse electroplating the developed areas. As a result, the resulting nickel substrate includes a pattern or representation of the microfiche images formed therein.

Referring to FIG. 10, after generating the metal substrate with the microfiche images formed therein, the metal substrate 720 is separated from the silicon base wafer 210. Specifically, an underside 1000 of the metal substrate 720 includes indentations or impressions 1010 corresponding to the mask 500. These impressions 1010 represent the pattern (320 or 430) of images 200a-x in the microfiche sheet 210. Persons of ordinary skill in the art will recognize that the impressions 910 formed within the underside 1000 of the substrate 720 can also be ridges or protrusions that fill holes or depressions of the mask 500 if negative photoresist is utilized. However, in both cases, the formations within the metal substrate 720 represent the pattern of microfiche images 200a-x.

In the alternative embodiments shown in FIGS. 8 and 9, there is no silicon base wafer. Rather, the images are formed directly into the nickel wafer to produce a nickel “substrate” with the images formed therein.

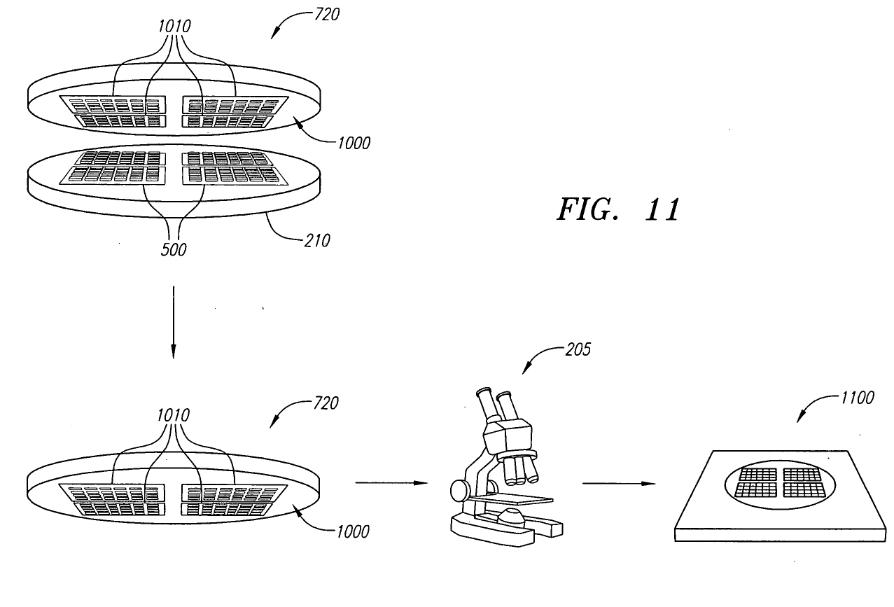

Continuing with reference to FIG. 11, the metal substrate 720 can be inspected with a microscope 205 or other inspection device to ensure that the microfiche images 200a-x were properly formed or developed into the metal substrate 720. Moreover, depending on the use of the substrate 720 and customer's needs, the substrate 720 can be mounted into a storage block or carrier 1100.

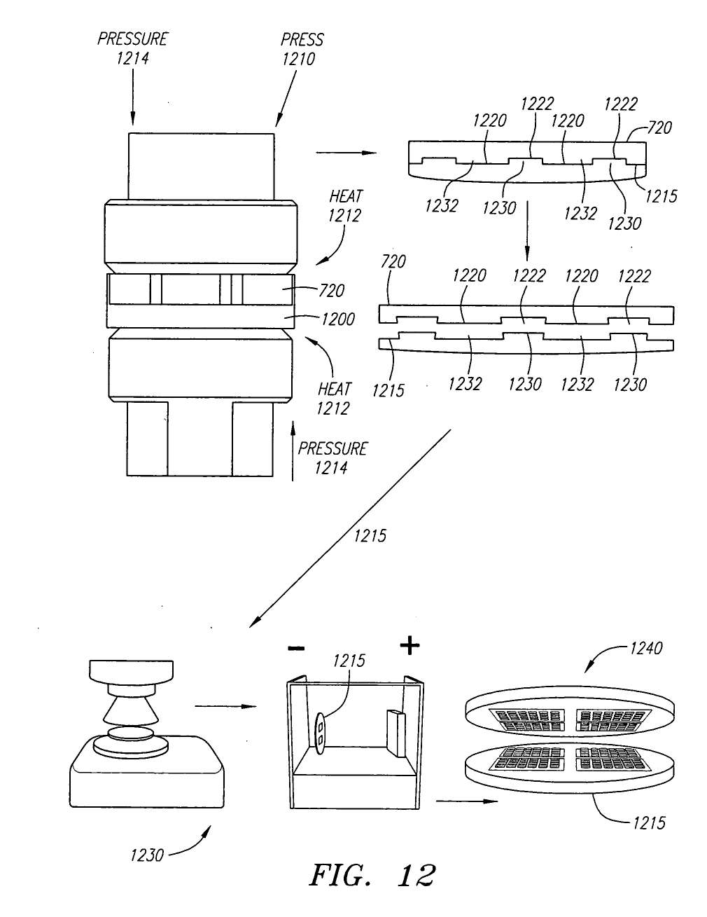

Further film image replication applications can be realized using the metal substrate 720 with film images or patterns formed therein. Referring to FIG. 12, a further aspect of the present invention involves replicating the images or patterns formed in the nickel substrate 720 to an elastic material. Specifically, a metal substrate 720 or “metal master” is placed on top of an elastic material 1200, such as a plastic block or “plastic blank.” The substrate 720 and plastic block 1200 are inserted into a press 1210 which applies heat 1212 and pressure 1214 to the substrate 720 and plastic block 1200. As a result, the plastic block 1215 is formed with impressions, ridges or indentations in the substrate 720. For example, the metal substrate 720 is shown as having ridges 1220 and 1222 representing one or more microfiche images or patterns. The metal substrate 720 is pressed down onto the blank plastic sheet or polymer 1200, such as acrylic. As a result, the blank plastic sheet 1200 is formed with ridges and indentations 1230, 1232 that are the “negative” of the impressions and ridges 1222, 1220 of the metal substrate 720 and also represent the microfiche sheet images or patterns. Persons of ordinary skill in the art will recognize that the formed plastic sheet 1215 can include impressions or protrusions if different photoresist is utilized. In either case, the plastic sheet 1215 is formed with representations of microfiche images.

This process can be further applied to produce an additional nickel substrate 1240, by the techniques previously described, having microfiche images or patterns formed therein from the formed plastic sheet 1215. In other words, the formed plastic 1215 serves as pattern against which a nickel substrate can be formed. For example, nickel can be electroplated 1230 over the formed plastic sheet 1215. The plastic sheet 1215 and nickel substrate 1240 are then separated, resulting in the microfiche images or patterns being formed within the new nickel substrate 1240. This replication process can be repeated as necessary to replicate the microfiche images in different materials.

The method and system of the present invention provide an improved technique for storing data, and specifically for replicating or reproducing images stored in a film to a metal substrate. By using a metal substrate, data storage capabilities are improved compared to known systems. Such an article of manufacture is more durable, thereby providing longer data storage capabilities and reducing media degradation. Moreover, more data can be stored to a smaller substrate, thereby increasing data storage capabilities compared to film. Further, metal substrates are immune or more resistant to environmental factors such as heat, water, humidity, fire and oxidation. Additionally, the data stored in a metal substrate can be retrieved via a microscope or other known optical system. As a result, the ability to view the data is not dependent on changing data formats or data storage equipment. Accordingly, the method and system of the present invention provide improved data storage capabilities and applications.

Persons of ordinary skill in the art will recognize that the above method and system can be implemented using different metal substrates. Moreover, those persons of ordinary skill will recognize that images in different types of film can be replicated onto various metal substrates to form different articles of manufacture. Moreover, depending on the photoresist and development system, the metal substrate can assume different forms or shapes to represent film images. Finally, the wavelength of the UV light source may vary depending on the type and characteristics of the film to be processed.

We claim:

1. A method of replicating one or more images stored in a film to a metal substrate, comprising:
preparing a base wafer with photoresist;
exposing said photoresist to a pattern representing the one or more images and derived from the film using a light source;
developing said exposed photoresist to form a mask of said pattern on said base wafer; and
forming a metal substrate with said pattern formed therein from said mask.

2. The method of claim 1, wherein said base wafer comprises a silicon base wafer.

3. The method of claim 1, wherein said pattern represents a photograph or alphanumeric text.

4. The method of claim 1, wherein said pattern represents a barcode or a matrix.

5. The method of claim 1, wherein said light source comprises an ultraviolet light source that emits radiation at about 280 nm to 400 nm.

6. The method of claim 1, wherein the film is microfiche, microfilm, projector film or camera film negative.

7. The method of claim 1, wherein said metal substrate with said pattern formed therein comprises a nickel substrate.

8. The method of claim 1, wherein said metal substrate is a gold substrate or a platinum substrate.

9. The method of claim 1, wherein exposing said photoresist to said pattern derived from the film further comprises:
placing the film onto said base wafer; and
activating said light source to illuminate the film, to expose said photoresist with said pattern.

10. The method of claim 1, wherein exposing said photoresist to said pattern derived from the film further comprises projecting said pattern derived from the film through one or more optical components onto said photoresist to expose said photoresist to said pattern.

11. The method of claim 10, wherein a first image of said pattern is projected through said one or more optical components to produce a second image of said pattern, said photoresist being exposed to said second image.

12. The method of claim 11, wherein said first image of said pattern is reduced by a factor of about 4:1 with said one or more optical components to form said second image of said pattern.

13. The method of claim 1, wherein forming said metal substrate further comprises:
depositing a base metal layer over said mask;
depositing one or more additional metal layers over said base metal layer and said base wafer to form said metal substrate.

14. The method of claim 13, wherein depositing said base metal layer further comprises sputtering said base metal layer.

15. The method of claim 13, wherein depositing one or more additional metal layers further comprises electroplating one or more additional metal layers over said base metal layer and said base wafer.

16. The method of claim 1, wherein said pattern is formed in an underside of said metal substrate.

17. The method of claim 1, further comprising separating said metal substrate and said base wafer.

18. The method of claim 17, further comprising removing said photoresist from said metal substrate.

19. The method of claim 1, further comprising replicating said film pattern formed in said metal substrate in an elastic material.

20. The method of claim 19, wherein said elastic material comprises a plastic sheet, the method further comprising:
placing said plastic sheet against said metal substrate with said film pattern formed therein; and
applying heat and pressure to said plastic sheet so that said plastic sheet forms a negative of said pattern formed in said metal substrate.

21. The method of claim 20, further comprising replicating said pattern formed in said plastic sheet in a second metal substrate.

22. The method of claim 1, wherein said pattern represents a single image or document.

23. The method of claim 1, wherein said pattern represents a plurality of images or documents.

24. The method of claim 1, wherein exposing said photoresist to said pattern representing the one or more images derived from the film further comprises exposing sections of said photoresist to sections of said pattern with a stepper/scanner.

25. A system for replicating one or more images stored in a film to a metal substrate, comprising:
a base wafer with photoresist;
a light source for exposing said photoresist to a pattern representing the one or more images and derived from the film, wherein said exposed photoresist is developed to form a mask representing said pattern;
a sputtering mechanism configured to deposit a metal seed layer over said base wafer with said mask; and
an electroplating system configured to deposit one or more additional metal layers over said metal seed layer and said base wafer to form a metal substrate, said metal substrate having said pattern formed therein.

26. The system of claim 25, wherein said base wafer comprises a silicon base wafer.

27. The system of claim 25, wherein said pattern represents a photograph or alpha-numeric text.

28. The system of claim 25, wherein said pattern represents a barcode or a matrix.

29. The system of claim 25, wherein said light source comprises an ultraviolet light source that emits radiation at about 280 nm to 400 nm.

30. The system of claim 25, wherein the film is microfiche, microfilm, projector film or camera film negative.

31. The system of claim 25, wherein said metal substrate with said pattern formed therein comprises a nickel substrate.

32. The system of claim 25, wherein said metal substrate is a gold substrate or a platinum substrate.

33. The system of claim 25, wherein the film is placed directly onto said base wafer with said photoresist, said light source being activated to expose said photoresist with said pattern representing the one or more film images.

34. The system of claim 25, further comprising one or more optical components, wherein a first image of said pattern is projected through said one or more optical components to produce a second image of said pattern, said second image being projected onto said photoresist to expose said photoresist with said pattern representing the one or more film images.

35. The system of 34, wherein said first image is reduced by a factor of about 4:1 with said one or more optical components to form said second image.

36. The system of claim 35, wherein said light source, the film, said one or more optical components, and said base wafer are arranged in a linear configuration.

37. The system of claim 25, wherein said sputtering mechanism comprises a plasma sputtering system.

38. The system of claim 25, further comprising a stepper/scanner configured to expose sections of said photoresist to sections of said pattern representing the one or more images derived from the film.

39. A system for replicating one or more images stored in a film to a metal substrate, comprising:
a nickel base wafer with photoresist;
a light source for exposing said photoresist with a pattern representing the one or more film images and derived from the film, wherein said exposed photoresist is developed to form a mask of said pattern, and
wherein said exposed base wafer with said photoresist is placed in an etch solution to remove nickel sections of said nickel base wafer that were exposed to said pattern, and wherein said photoresist is removed to form said metal substrate having the one or more film images etched therein.

40. A system for replicating one or more images stored in a film to a metal substrate, comprising
a nickel base wafer with photoresist;
a light source for exposing said photoresist with a pattern representing the one or more film images and derived from the film, wherein said exposed photoresist is developed to form a mask of said pattern; and
a reverse electroplating system,
wherein said reverse electroplating system removes nickel sections from said nickel base wafer that were exposed with said pattern to form said metal substrate having the one or more images formed therein.

41. An article of manufacture comprising a metal substrate having one more film images formed therein, the metal substrate being formed by the method of
preparing a base wafer with photoresist;
exposing said photoresist to a pattern representing the one or more images and derived from the film using a light source;
developing said exposed photoresist to form a mask of said pattern;
forming a metal substrate with said pattern formed therein from said mask of the film; and
separating said metal substrate and said base wafer.

42. The article of manufacture of claim 41, wherein said base wafer comprises a silicon base wafer.

43. The article of manufacture of claim 41, wherein said pattern represents a photograph or alpha-numeric text.

44. The article of manufacture of claim 41, wherein said pattern represents a barcode or a matrix.

45. The article of manufacture of claim 41, wherein said light source comprises an ultraviolet light source configured to emit radiation at about 280 nm to 400 nm.

46. The article of manufacture of claim 41, wherein the film is microfiche, microfilm, projector film, or camera film.

47. The article of manufacture of claim 41, wherein said metal substrate comprises a nickel substrate.

48. The article of manufacture of claim 41, wherein said metal substrate is a gold substrate or a platinum substrate.

49. The article of manufacture of claim 41, wherein exposing said base wafer with said photoresist to said pattern further comprises
placing the film onto said base wafer; and
activating said light source to illuminate the film, to expose said photoresist with said pattern representing the one or more film images.

50. The article of manufacture of claim 41, wherein exposing said photoresist with said pattern further comprises projecting a first image of said pattern through one or more optical components to form a second image of said pattern and projecting said second image onto said photoresist, thereby exposing said photoresist with said pattern.

51. The article of manufacture of claim 50, wherein said first image is reduced by a factor of about 4:1 with said one or more optical components to form said second image.

52. The article of manufacture of claim 41, wherein forming said metal substrate further comprises
depositing a base metal layer over said mask;
depositing one or more additional metal layers over said base metal layer and said base wafer, thereby forming said metal substrate.

53. The article of manufacture of claim 41, wherein forming said base metal layer further comprises sputtering said base metal layer over said mask.

54. The article of manufacture of claim 53, wherein depositing one or more additional metal layers further comprises electroplating one or more additional metal layers over said base metal layer and said base wafer.

55. The article of manufacture of claim 41, wherein said pattern representing the one or more film images is formed in an underside of said metal substrate.

56. The article of manufacture of claim 41, further comprising a package for storing said metal substrate having said pattern representing the one or more film images formed therein.
